(19) United States
(12) Patent Application Publication
(10) Pub. No.: US 2019/0189922 A1
(43) Pub. Date: Jun. 20, 2019

(54) METHOD FOR PRODUCING SEMICONDUCTOR NANOPARTICLE COMPLEX, SEMICONDUCTOR NANOPARTICLE COMPLEX, AND FILM

(71) Applicant: FUJIFILM Corporation, Tokyo (JP)

(72) Inventor: Hiroshi ISOJIMA, Kanagawa (JP)

(73) Assignee: FUJIFILM Corporation, Tokyo (JP)

(21) Appl. No.: 16/283,842

(22) Filed: Feb. 25, 2019

Related U.S. Application Data
(63) Continuation of application No. PCT/JP2017/030071, filed on Aug. 23, 2017.

(30) Foreign Application Priority Data
Aug. 31, 2016 (JP) 2016-168955

(51) Int. Cl. H01L 51/00; H01L 51/05

(52) U.S. Cl. CPC H01L 51/0002; H01L 51/0587

(57) ABSTRACT

An object of the present invention is to provide a method for producing a semiconductor nanoparticle complex, which is capable of suppressing aggregation of particles and forming a good coating with an oxide, a semiconductor nanoparticle complex, and a film. The method for producing a semiconductor nanoparticle complex of the present invention is a method for producing a semiconductor nanoparticle complex including a coating step of coating a semiconductor nanoparticle with a silane having a group represented by a predetermined formula to obtain a coated semiconductor nanoparticle; a hydrophilization step of mixing the coated semiconductor nanoparticle with a reverse micelle solution to obtain a reverse micelle solution containing a hydrophilized coated semiconductor nanoparticle; and an oxide-containing layer forming step of forming an oxide-containing layer on the surface of the hydrophilized coated semiconductor nanoparticle by adding an alkoxide to the reverse micelle solution after the hydrophilization step to obtain the semiconductor nanoparticle complex.

### CROSS-REFERENCE TO RELATED APPLICATIONS

This application is a Continuation of PCT International Application No. PCT/JP2017/030071 filed on Aug. 23, 2017, which claims priority under 35 U.S.C. § 119(a) to Japanese Patent Application No. 2016-168955 filed on Aug. 31, 2016. The above application is hereby expressly incorporated by reference, in its entirety, into the present application.

### BACKGROUND OF THE INVENTION

### 1. Field of the Invention

The present invention relates to a method for producing a semiconductor nanoparticle complex, a semiconductor nanoparticle complex, and a film.

### 2. Description of the Related Art

Single nano-sized colloidal semiconductor nanoparticles (hereinafter, also referred to as “quantum dots”), obtained by a chemical synthesis method in a solution containing a metal element, have been put into practical use as fluorescent materials in wavelength conversion films for some display applications. In addition, quantum dots are expected to be applied to biological labels, light emitting diodes, solar cells, thin film transistors, and the like.

For the purpose of improving the durability and the like of such quantum dots, it is known to coat the surface of the particle with an oxide (particularly silica). For example, there is known a method in which the surface of a Cd-based quantum dot is coated with aminopropyltrimethoxysilane and then ammonia and tetraethyl orthosilicate (TEOS) are added thereto (reverse micelle method) (JP2008-516782A, WO2012/161065A, and JP2015-504459A).

Here, the reverse micelle method is a method in which a water phase is dispersed in an organic solvent (oil phase) by a surfactant to form water droplets in the oil phase, that is, ones in which micelles are formed (reverse micelles), and a substance is synthesized using water droplets of the reverse micelles as a reaction field.

### SUMMARY OF THE INVENTION

Meanwhile, since a Cd or Pb element is a substance regulated by Restriction on Hazardous Substances (Rohs) and the like, research on quantum dots not containing Cd or Pb has also been proposed in recent years.

The present inventors have applied the oxide coating using the reverse micelle method described in JP2008-516782A, WO2012/161065A, and JP2015-504459A to In-based quantum dots and found that aggregation occurred in the particles and the coating with an oxide did not sufficiently proceed.

Accordingly, an object of the present invention is to provide a method for producing a semiconductor nanoparticle complex, which is capable of suppressing aggregation of particles and forming a good coating with an oxide, a semiconductor nanoparticle complex, and a film.

As a result of extensive studies to achieve the foregoing object, the present inventors have found that it is possible to suppress aggregation of particles and to form a good coating with an oxide by coating nanoparticles with a predetermined silane and then adding an alkoxide to form an oxide. The present invention has been completed based on these findings.

That is, it has been found that the foregoing object can be achieved by the following configuration.

[1] A method for producing a semiconductor nanoparticle complex, comprising:

a coating step of coating a semiconductor nanoparticle with a silane having a group represented by Formula (1) to obtain a coated semiconductor nanoparticle;

a hydrophilization step of mixing the coated semiconductor nanoparticle with a reverse micelle solution to obtain a reverse micelle solution containing a hydrophilized coated semiconductor nanoparticle; and an oxide-containing layer forming step of forming an oxide-containing layer on the surface of the hydrophilized coated semiconductor nanoparticle by adding an alkoxide to the reverse micelle solution after the hydrophilization step to obtain the semiconductor nanoparticle complex,

X-L-* (1)

in Formula (1), X represents an active hydrogen-containing group, L represents an alkylene group having 8 to 17 carbon atoms, and * represents a bonding position with a silicon atom.

[2] The method for producing a semiconductor nanoparticle complex according to [1], in which the semiconductor nanoparticle contains a Group III element and a Group V element.

[3] The method for producing a semiconductor nanoparticle complex according to [2], in which the Group III element is In and the Group V element is any one of P, N, or As.

[4] The method for producing a semiconductor nanoparticle complex according to [3], in which the Group III element is In and the Group V element is P.

[5] The method for producing a semiconductor nanoparticle complex according to any one of [1] to [4], in which the silane is represented by Formula (2),

X-L-Si(OR)₃ (2)

in Formula (2), X represents an active hydrogen-containing group, L represents an alkylene group having 8 to 17 carbon atoms, R represents a methyl group or an ethyl group, and a plurality of R's may be the same or different.

[6] The method for producing a semiconductor nanoparticle complex according to any one of [1] to [5], in which the active hydrogen-containing group is any one of a mercapto group, a carboxyl group, a hydroxyl group, an amino group, a phosphate group, or a sulfo group.

[7] The method for producing a semiconductor nanoparticle complex according to [6], in which the active hydrogen-containing group is a mercapto group.

[8] The method for producing a semiconductor nanoparticle complex according to any one of [1] to [7], in which the alkoxide is an alkoxysilane.

[9] The method for producing a semiconductor nanoparticle complex according to [8], in which an oxide contained in the oxide-containing layer is silica.

[10] A semiconductor nanoparticle complex comprising: a semiconductor nanoparticle; a coating layer covering at least a part of the semiconductor nanoparticle; and an oxide-containing layer covering at least a part of the coating layer, in which the coating layer has a structure represented by Formula (3),

*₁-Y-L-*₂ (3)

in Formula (3), Y represents a divalent group obtained by removing active hydrogen from an active hydrogen-containing group, L represents an alkylene group having 8 to 17 carbon atoms, *₁ represents a bonding position with the semiconductor nanoparticle, and *₂ represents a bonding position with the oxide-containing layer.

[11] The semiconductor nanoparticle complex according to [10], in which the semiconductor nanoparticle contains a Group III element and a Group V element.

[12] The semiconductor nanoparticle complex according to [11], in which the Group III element is In and the Group V element is any one of P, N, or As.

[13] The semiconductor nanoparticle complex according to [12], in which the Group III element is In and the Group V element is P.

[14] The semiconductor nanoparticle complex according to any one of [10] to [13], in which the active hydrogen-containing group is any one of a mercapto group, a carboxyl group, a hydroxyl group, an amino group, a phosphate group, or a sulfo group.

[15] The semiconductor nanoparticle complex according to [14], in which the active hydrogen-containing group is a mercapto group.

[16] A film comprising the semiconductor nanoparticle complex according to any one of [10] to [15].

According to the present invention, it is possible to provide to a method for producing a semiconductor nanoparticle complex, which is capable of suppressing aggregation of particles and forming a good coating with an oxide, a semiconductor nanoparticle complex, and a film.

### BRIEF DESCRIPTION OF THE DRAWINGS

FIG. 1 is a schematic cross-sectional view showing an example of an embodiment of a semiconductor nanoparticle complex of the present invention.

FIG. 2 is an image (TEM image) obtained by capturing a dispersion liquid of the semiconductor nanoparticle complex prepared in Example 1 with a transmission electron microscope (TEM).

FIG. 3 is a TEM image of a dispersion liquid of the semiconductor nanoparticle complex prepared in Example 2.

FIG. 4 is a TEM image of a dispersion liquid of the semiconductor nanoparticle complex prepared in Comparative Example 1.

FIG. 5 is a TEM image of a dispersion liquid of the semiconductor nanoparticle complex prepared in Comparative Example 2.

FIG. 6 is a graph showing the particle size distribution of the semiconductor nanoparticle complex prepared in Example 1.

### DESCRIPTION OF THE PREFERRED EMBODIMENTS

Hereinafter, the present invention will be described in detail.

Descriptions of the constituent features described below are sometimes made based on representative embodiments of the present invention, but the present invention is not limited to such embodiments.

In the present specification, a numerical range expressed using “to” means a range including numerical values described before and after “to” as a lower limit value and an upper limit value, respectively.

[Method for Producing Semiconductor Nanoparticle Complex]

The method for producing a semiconductor nanoparticle complex according to the embodiment of the present invention (hereinafter, also simply referred to as “production method according to the embodiment of the present invention”) has a coating step of coating a semiconductor nanoparticle with a silane having a group represented by Formula (1) to obtain a coated semiconductor nanoparticle.

X-L-* (1)

in Formula (1), X represents an active hydrogen-containing group, L represents an alkylene group having 8 to 17 carbon atoms, and * represents a bonding position with a silicon atom.

Further, the production method according to the embodiment of the present invention has a hydrophilization step of mixing the coated semiconductor nanoparticle with a reverse micelle solution to obtain a reverse micelle solution containing a hydrophilized coated semiconductor nanoparticle, following the coating step.

Further, the production method according to the embodiment of the present invention has an oxide-containing layer forming step of forming an oxide-containing layer on the surface of the hydrophilized coated semiconductor nanoparticle by adding an alkoxide to the reverse micelle solution after the hydrophilization step to obtain the semiconductor nanoparticle complex.

In the production method according to the embodiment of the present invention, it is possible to suppress aggregation of particles and form a good coating with an oxide since the hydrophilization step and the oxide-containing layer forming step are carried out after the coating step of coating semiconductor nanoparticles with a predetermined silane having a group represented by Formula (1).

The reason why the aggregation of particles is suppressed and a good coating with an oxide can be formed as described above is not clear in detail, but it is presumed to be approximately as follows.

That is, it is necessary to render semiconductor nanoparticles hydrophilic in the case of coating an oxide on the surface of the semiconductor nanoparticles using a reverse micelle method, but the present inventors have surmised that, in the case where aminopropyltrimethoxysilane or TEOS described in JP2008-516782A, WO2012/161065A, and JP2015-504459A is used as the silane used for such hydrophilization, at the time of the hydrophilization treatment, these silanes deviate from the surface of the semiconductor nanoparticles (in particular, In-based quantum dots), and the semiconductor nanoparticles would aggregate in the oil phase.

Therefore, it is considered that, by using a predetermined silane having a group represented by Formula (1) in the coating step in the production method according to the embodiment of the present invention, silane coated on the surface of the semiconductor nanoparticles was stably coordinated also in the hydrophilization step, and as a result, aggregation of the semiconductor nanoparticles in the oil phase was suppressed, hydrophilization and formation of subsequent oxides were also improved.

Next, the coating step, the hydrophilization step, and the oxide-containing layer forming step included in the production method according to the embodiment of the present invention will be described in detail.

[Coating Step]

The coating step included in the production method according to the embodiment of the present invention is a step of obtaining a coated semiconductor nanoparticle by coating a semiconductor nanoparticle with a silane having a group represented by Formula (1) which will be described below.

<Semiconductor Nanoparticles>

Semiconductor nanoparticles used in the coating step are not particularly limited, and examples thereof include a Group II-VI semiconductor containing a Group II element and a Group VI element, a Group III-V semiconductor containing a Group III element and a Group V element, a Group III-VI semiconductor containing a Group III element and a Group VI element, and a Group IV-VI semiconductor containing a Group IV element and a Group VI element.

Among them, a so-called Group III-V semiconductor containing a Group III element and a Group V element is preferable for reasons of excellent light emitting characteristics in the visible light range.

(Group III Element)

Specific examples of the Group III element include indium (In), aluminum (Al), and gallium (Ga), among which In is preferable.

(Group V Element)

Specific examples of the Group V element include phosphorus (P), nitrogen (N), and arsenic (As), among which P is preferable.

In the present invention, the semiconductor nanoparticles are preferably quantum dots not doped with rare earth ions and transition metal ions from the viewpoint of fluorescence characteristics, specifically, InP, InN, and InAs are preferable, and among them, InP is more preferable.

In the present invention, the semiconductor nanoparticle preferably has a core-shell structure including a core (particularly InP) containing the Group III element and the Group V element described above and a shell covering at least a part of the surface of the core.

Here, whether or not at least a part of the surface of the core is covered with the shell can also be confirmed by the composition distribution analysis based on, for example, transmission electron microscope (TEM)-energy dispersive X-ray spectroscopy (EDX).

In the case where the semiconductor nanoparticle has a core-shell structure, the shell is preferably a so-called Group II-VI semiconductor containing a Group II element and a Group VI element.

(Group II Element)

Specific examples of the Group II element include zinc (Zn), cadmium (Cd), and magnesium (Mg), among which Zn is preferable.

(Group VI Element)

Specific examples of the Group VI element include sulfur (S), oxygen (O), selenium (Se), and tellurium (Te), among which S or Se is preferable, and S is more preferable.

In the present invention, a Group II-VI semiconductor obtained by appropriately combining the Group II elements and the Group VI elements exemplified above can be used as the shell, but it is preferred that the shell is a crystal system which is the same as or similar to the core described above.

Specifically, ZnS or ZnSe is preferable and from the viewpoint of safety or the like, ZnS is more preferable.

In addition, the shell may have a gradient composition in which compositions of In, Zn, P, S and the like change in the thickness direction of the shell.

In the case where the semiconductor nanoparticle has a core-shell structure, the shell may have a first shell covering at least a part of the surface of the core and a second shell covering at least a part of the first shell.

Specifically, there is an aspect having a first shell made of a Group III-V semiconductor containing a Group III element and a Group V element and a second shell made of a Group II-VI semiconductor containing a Group II element and a Group VI element.

(First Shell)

Specific examples of the Group III element contained in the Group III-V semiconductor as the first shell include indium (In), aluminum (Al), and gallium (Ga), among which Ga is preferable.

Note that the Group III element contained in the Group III-V semiconductor as the first shell is preferably a Group III element different from the Group III element contained in the core described above. For example, in the case where the Group III element contained in the core is In, the Group III element contained in the Group III-V semiconductor as the first shell is Al, Ga, or the like.

Specific examples of the Group V element contained in the Group III-V semiconductor include P (phosphorus), N (nitrogen), and As (arsenic), among which P is preferable.

A Group III-V semiconductor obtained by appropriately combining the Group III elements and the Group V elements exemplified above can be used as the first shell, but it is preferred that the first shell is a crystal system (for example, a zinc blende structure) which is the same as or similar to the core described above. Specifically, GaP is preferable.

(Second Shell)

The Group II-VI semiconductor as the second shell is the same as that for the above-mentioned shell, among which ZnS or ZnSe is preferable, and from the viewpoint of safety or the like, ZnS is more preferable.

From the viewpoints of easily synthesizing particles having a uniform size and easily controlling the emission wavelength using quantum size effects, the average particle diameter of the semiconductor nanoparticles used in the coating step is preferably 2 nm or more and more preferably 10 nm or less.

Here, the average particle diameter refers to a value obtained by directly observing at least 20 particles using a transmission electron microscope, calculating the diameters of circles having the same area as the projected area of the particles, and arithmetically averaging the calculated values.

From the viewpoint of workability, the semiconductor nanoparticles used in the coating step are preferably used in the form of a dispersion liquid dispersed in a dispersion medium.

Here, the solvent constituting the dispersion medium of the dispersion liquid is preferably a nonpolar solvent.

Specific examples of the nonpolar solvent include aromatic hydrocarbon such as toluene; halogenated alkyl such as chloroform; aliphatic saturated hydrocarbon such as hexane, octane, n-decane, n-dodecane, n-hexadecane, or n-octadecane; aliphatic unsaturated hydrocarbon such as 1-undecene, 1-dodecene, 1-hexadecene, or 1-octadecene; and trioctylphosphine.

The content (concentration) of the semiconductor nanoparticles in the dispersion liquid is preferably 0.1 to 100 mmol/L and more preferably 1 to 100 mmol/L, with respect to the total mass of the dispersion liquid.

<Silane>

The silane used in the coating step is a silane having a group represented by Formula (1).

X-L-* (1)

In Formula (1), X represents an active hydrogen-containing group, L represents an alkylene group having 8 to 17 carbon atoms, and * represents a bonding position with a silicon atom.

For the reason that a dense oxide-containing layer is obtained, it is preferable in the present invention that the silane having a group represented by Formula (1) is a silane represented by Formula (2).

X-L-Si(OR)₃ (2)

In Formula (2), X represents an active hydrogen-containing group, L represents an alkylene group having 8 to 17 carbon atoms, R represents a methyl group or an ethyl group, and a plurality of R's may be the same or different.

The alkylene group having 8 to 17 carbon atoms represented by L in Formulae (1) and (2) is preferably linear, and examples thereof include an n-octylene group, an n-decylene group, an n-undecylene group, and an n-dodecylene group.

The active hydrogen-containing group represented by X in Formulae (1) and (2) is preferably any one of a mercapto group (—SH), a carboxyl group (—COOH), a hydroxyl group (—OH), an amino group (—NH₂), a phosphate group (—PO₄H₂), or a sulfo group (—SO₃H), and among which a mercapto group is preferable because it can be stably bonded to the surface of the semiconductor nanoparticles, particularly the shell surface of the semiconductor nanoparticles having ZnS in the shell.

Specific examples of the silane represented by Formula (2) include 12-mercaptododecyltrimethoxysilane, 11-mercaptoundecyltrimethoxysilane, 10-mercaptodecyltrimethoxysilane, 9-mercaptononyltrimethoxysilane, 8-mercaptooctyl trimethoxysilane, and 11-mercaptoundecyltriethoxysilane.

<Treatment Method>

In the coating step, the method for obtaining coated semiconductor nanoparticles coated using the silane described above is not particularly limited, and the same method as the general ligand exchange reaction or the like can be adopted as appropriate. For example, there is a method in which the silane described above is added to the dispersion liquid described above in which the semiconductor nanoparticles are dispersed, followed by mixing at a temperature condition of 50° C. to 100° C. for 6 to 24 hours.

[Hydrophilization Step]

The hydrophilization step included in the production method according to the embodiment of the present invention is a step of mixing the coated semiconductor nanoparticles with a reverse micelle solution to obtain a reverse micelle solution containing hydrophilized coated semiconductor nanoparticles, following the coating step.

Herein, the reverse micelle solution refers to a solution in which a surfactant and a small amount of water are added to a hydrophobic organic solvent to form a water droplet (reverse micelle) dispersed in an oil phase (organic solvent).

The hydrophobic organic solvent may be, for example, a hydrocarbon having 4 to 12 carbon atoms, and specific examples thereof include a linear, branched, or cyclic aliphatic hydrocarbon having 4 to 12 carbon atoms, or an aromatic hydrocarbon having 6 to 12 carbon atoms.

The above-mentioned aliphatic hydrocarbon may be either saturated or unsaturated as long as the melting point and boiling point thereof are not in the range of 10° C. to 35° C. and it is a liquid at ordinary temperature (23° C.). A linear, branched or cyclic saturated aliphatic hydrocarbon having 5 to 10 carbon atoms is preferred. More specific examples of the aliphatic hydrocarbon include pentane, cyclopentane, hexane, cyclohexane, heptane, isoheptane, octane, isooctane, nonane, and decane, among which cyclohexane is particularly preferable.

The aromatic hydrocarbon is a monocyclic or bicyclic aromatic hydrocarbon and may have an aliphatic hydrocarbon group on the aromatic ring. More specific examples of the aromatic hydrocarbon include benzene, toluene, and xylene.

The surfactant is not particularly limited as long as it is dissolved in a hydrophobic organic solvent and in the dissolved state, it is capable of forming a so-called reverse micelle in which the hydrophobic group side of the surfactant is oriented outward and the hydrophilic group side of the surfactant is oriented inward.

Specific examples of the surfactant include polyoxyethylene alkyl aryl ethers such as polyoxyethylene octyl phenyl ether and polyoxyethylene nonyl phenyl ether.

The reverse micelle is prepared by adding a surfactant to a hydrophobic organic solvent, followed by stirring. The amount of the surfactant to be used is preferably about 0.001 to 0.1 mol and more preferably about 0.005 to 0.02 mol per 1 mol of the hydrophobic organic solvent.

The temperature at the time of stirring is not particularly limited, but it may be usually about 10° C. to 35° C. In order to produce a reverse micelle having a uniform size, it is necessary to stir vigorously the solution.

Thus, a reverse micelle having an average diameter (outer diameter) of about 5 to 20 nm is formed.

<Treatment Method>

In the hydrophilization step, the method of hydrophilizing coated semiconductor nanoparticles using a reverse micelle solution is not particularly limited, and a reverse micelle solution containing hydrophilized coated semiconductor nanoparticles can be obtained by mixing the coated semiconductor nanoparticles and the reverse micelle solution.

The method of mixing the coated semiconductor nanoparticles and the reverse micelle solution is not particularly limited. For example, there is a method in which a dispersion liquid of the coated semiconductor nanoparticles is added to the reverse micelle solution, followed by mixing at a temperature of 20° C. to 80° C. for 30 minutes to 6 hours.

[Oxide-Containing Layer Forming Step]

The oxide-containing layer forming step included in the production method according to the embodiment of the present invention is a step of forming an oxide-containing layer on the surface of the hydrophilized coated semiconductor nanoparticle by adding an alkoxide to the reverse micelle solution after the hydrophilization step to obtain the semiconductor nanoparticle complex.

<Alkoxide>

The alkoxide may be, for example, a metal alkoxide.

As the metal of the metal alkoxide, it is preferable to use a metal atom easily breakable from various bonds by the action of water. Specifically, silicon, titanium, indium, tantalum, gallium, aluminum, and the like can be mentioned.

In the present invention, it is preferable that the alkoxide is a silicon alkoxide, that is, an alkoxysilane for the reason that a dense oxide-containing layer is obtained.

Here, the alkoxysilane is an alkoxysilane other than the silane having a group represented by Formula (1), and specific examples thereof include tetraethyl orthosilicate (TEOS), tetramethoxysilane, tetrapropoxysilane, methyltriethoxysilane, and methyltrimethoxysilane, among which TEOS is preferable.

<Oxide>

The oxide contained in the oxide-containing layer is not particularly limited as long as it is stable in the atmosphere and does not inhibit the light emission of quantum dots. Specific examples of the oxide include SiO₂, TiO₂, In₂O₃, Ta₂O₅, Ga₂O₃, and Al₂O₃, among which silica (SiO₂) formed using alkoxysilane is preferable.

<Treatment Method>

The method of forming an oxide-containing layer is not particularly limited, and an oxide-containing layer can be formed on the surface of the hydrophilized coated semiconductor nanoparticles by adding an alkoxide to the reverse micelle solution after the hydrophilization step.

From the viewpoint of obtaining a dense oxide-containing layer, the amount of the alkoxide to be added is preferably 5,000 times to 100,000 times (in terms of mol) and more preferably 10,000 times to 50,000 times (in terms of mol) with respect to one particle of the hydrophilized coated semiconductor nanoparticles.

In addition, in the case where an alkoxide is added, it is preferable to use an acid catalyst or an alkali catalyst, and from the viewpoint of forming a dense silica film, it is more preferable to use an alkali and it is still more preferable to use aqueous ammonia.

[Semiconductor Nanoparticle Complex]

The semiconductor nanoparticle complex according to the embodiment of the present invention is a semiconductor nanoparticle complex having semiconductor nanoparticles, a coating layer covering at least a part of the semiconductor nanoparticles, and an oxide-containing layer covering at least a part of the coating layer.

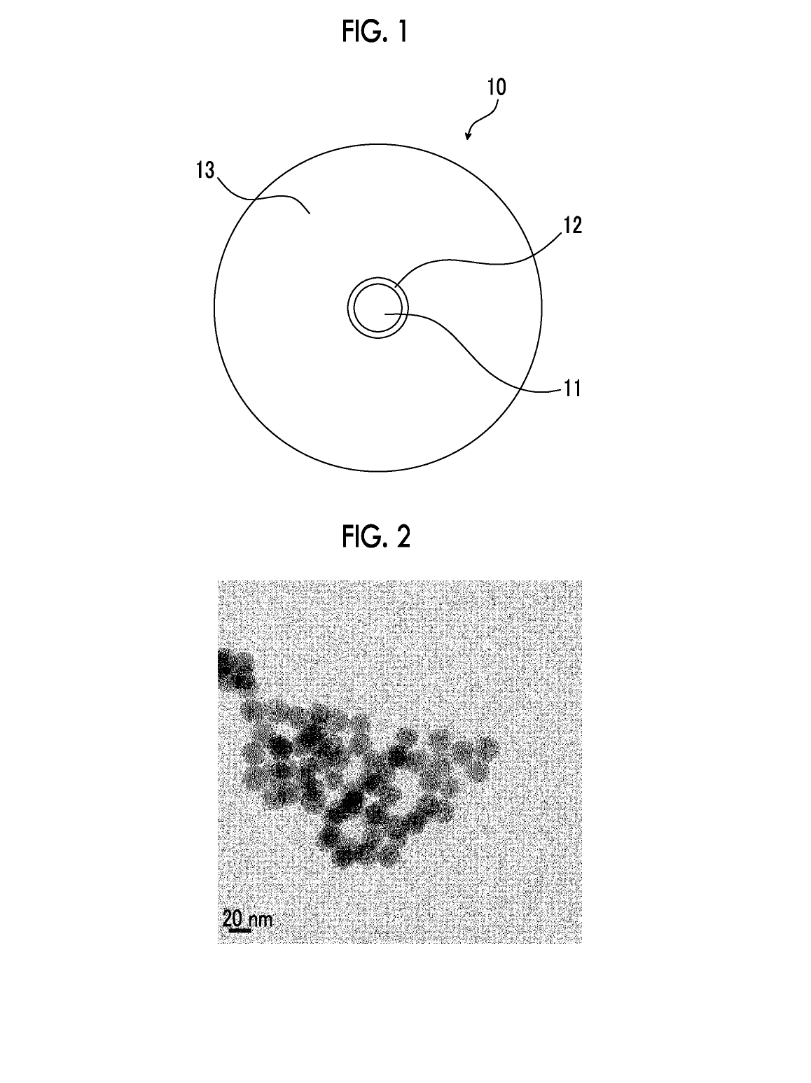

As shown in FIG. 1, a semiconductor nanoparticle complex 10 according to the embodiment of the present invention preferably includes semiconductor nanoparticles 11, a coating layer 12 covering the entire surface of the semiconductor nanoparticles 11, and an oxide-containing layer 13 covering the entire surface of the coating layer 12.

<Semiconductor Nanoparticle>

The semiconductor nanoparticles of the semiconductor nanoparticle complex according to the embodiment of the present invention are the same as the semiconductor nanoparticles described in the production method according to the embodiment of the present invention.

<Coating Layer>

The coating layer of the semiconductor nanoparticle complex according to the embodiment of the present invention has a structure represented by Formula (3).

*₁-Y-L-*₂ (3)

In Formula (3), Y represents a divalent group obtained by removing active hydrogen from an active hydrogen-containing group, L represents an alkylene group having 8 to 17 carbon atoms, *₁ represents a bonding position with the semiconductor nanoparticle, and *₂ represents a bonding position with the oxide-containing layer.

The alkylene group having 8 to 17 carbon atoms represented by L in Formula (3) is preferably linear, and examples thereof include an n-octylene group, an n-decylene group, an n-undecylene group, and an n-dodecylene group.

Further, the divalent group obtained by removing active hydrogen from the active hydrogen-containing group, which is represented by Y in Formula (3), is —S— in the case where the active hydrogen-containing group is a mercapto group (—SH); —C(═O)O— in the case where the active hydrogen-containing group is a carboxyl group (—COOH); —O— in the case where the active hydrogen-containing group is a hydroxyl group (—OH); —NH— in the case where the active hydrogen-containing group is an amino group (—NH₂); —OP(═O)(OH)O— in the case where the active hydrogen-containing group is a phosphate group (—PO₄H₂); and —S(═O)₂O— in the case where the active hydrogen-containing group is a sulfo group (—SO₃H).

Among these, the divalent group is preferably —S— because it can be stably bonded to the surface of the semiconductor nanoparticles, particularly the shell surface of the semiconductor nanoparticles having ZnS in the shell.

<Oxide-Containing Layer>

The oxide-containing layer included in the semiconductor nanoparticle complex according to the embodiment of the present invention may be, for example, a layer containing an oxide such as SiO₂, TiO₂, In₂O₃, Ta₂O₅, Ga₂O₃, or Al₂O₃.

[Film]

The film according to the embodiment of the present invention is a film containing the semiconductor nanoparticle complex according to the embodiment of the present invention described above.

Since such a film according to the embodiment of the present invention has a good durability, the film can be applied to, for example, a wavelength conversion film for a display, a photoelectron conversion (or wavelength conversion) film of a solar cell, a biological label, a thin film transistor, and the like. In particular, since the film according to the embodiment of the present invention is considered to exhibit an excellent durability against ultraviolet rays or the like, it is suitably applied to a down-conversion or down-shifting type wavelength conversion film which absorbs light in a range of shorter wavelengths than those of the absorption edge of quantum dots and emits light of longer wavelengths.

Further, the film material as a base material constituting the film according to the embodiment of the present invention is not particularly limited and may be a resin or a thin glass film.

Specific examples thereof include resin materials mainly formed of an ionomer, polyethylene, polyvinyl chloride, polyvinylidene chloride, polyvinyl alcohol, polypropylene, polyester, polycarbonate, polystyrene, polyacrylonitrile, an ethylene vinyl acetate copolymer, an ethylene-vinyl alcohol copolymer, an ethylene-methacrylic acid copolymer film, nylon, and the like.

### EXAMPLES

Hereinafter, the present invention will be described in more detail with reference to Examples. The materials, the use amounts, the ratios, the treatment contents, the treatment procedures, and the like shown in the following Examples can be appropriately changed without departing from the gist of the present invention. Therefore, the scope of the present invention should not be limitatively interpreted by the following Examples.

### Example 1

<Synthesis of Semiconductor Nanoparticle QDs>

32 mL of octadecene, 140 mg (0.48 mmol) of indium acetate, 48 mg (0.26 mmol) of zinc acetate, and 485 mg (1.89 mmol) of palmitic acid were added into a flask, and the mixture was heated and stirred at 110° C. under vacuum to sufficiently dissolve the raw materials and degassing was carried out.

Then, the temperature of the flask was raised to 300° C. under nitrogen flow, and in the case where the temperature of the solution was stabilized, 0.18 mmol of tristrimethylsilylphosphine dissolved in about 4 mL of octadecene was added. Thereafter, the solution was kept at 230° C. for 120 minutes. It was confirmed that the solution was colored in red, and particles (cores) were formed.

Next, in a state where the solution was heated to 200° C., 30 mg (0.18 mmol) of gallium chloride and 188 μL (0.6 mmol) of oleic acid dissolved in 8 mL of octadecene were added, followed by heating for about 1 hour to obtain a dispersion liquid of core-shell particle precursors having Zn-doped InP (core) and GaP (first shell).

Subsequently, the temperature of the dispersion liquid was cooled to room temperature, 0.93 mmol of zinc oleate was added, and the dispersion liquid was heated to 240° C. and kept for about 4 hours. Thereafter, 0.55 mL (2.3 mmol) of dodecanethiol was added and the dispersion liquid was kept for about 2 hours to obtain a dispersion liquid of core-shell particles having Zn-doped InP (core), GaP (first shell) covering the surface of the core, and ZnS (second shell) covering the surface of the first shell.

Next, acetone was mixed with the dispersion liquid to precipitate the particles, followed by centrifugation. The recovered precipitate was mixed with toluene to obtain a toluene dispersion liquid of InP/GaP/ZnS nanoparticles coordinated with dodecanethiol.

<Individual Steps>

Subsequently, mercaptoundecyltrimethoxysilane was added to the toluene dispersion liquid which was then kept at 65° C. for 24 hours to prepare coated semiconductor nanoparticles coated with a silane (coating step).

Then, a reverse micelle solution was prepared by mixing polyoxyethylene nonylphenyl ether (IGEPAL CO-520, manufactured by Sigma-Aldrich, Inc.), 9 ml of cyclohexane and 40 μL of aqueous ammonia. The coated semiconductor nanoparticles were added to the reverse micelle solution which was then stirred to be mixed for 30 minutes (hydrophilization step).

Next, after the hydrophilization step, 100 μl of TEOS and 400 μL of aqueous ammonia were added thereto, followed by stirring for 10 hours (oxide-containing layer forming step).

Then, the treatment of washing the precipitate after centrifugation with ethanol was repeated three times to carry out purification, thereby preparing an ethanol dispersion liquid of the silica-coated semiconductor nanoparticle complex.

### Example 2

A dispersion liquid of a semiconductor nanoparticle complex was prepared in the same manner as in Example 1, except that mercaptooctyltrimethoxysilane was used in place of mercaptoundecyltrimethoxysilane.

### Comparative Example 1

A dispersion liquid of a semiconductor nanoparticle complex was prepared in the same manner as in Example 1, except that mercaptopropyltrimethoxysilane was used in place of mercaptoundecyltrimethoxysilane.

### Comparative Example 2

A dispersion liquid of a semiconductor nanoparticle complex was prepared in the same manner as in Example 1, except that TEOS was used also in the coating step in place of mercaptoundecyltrimethoxysilane.

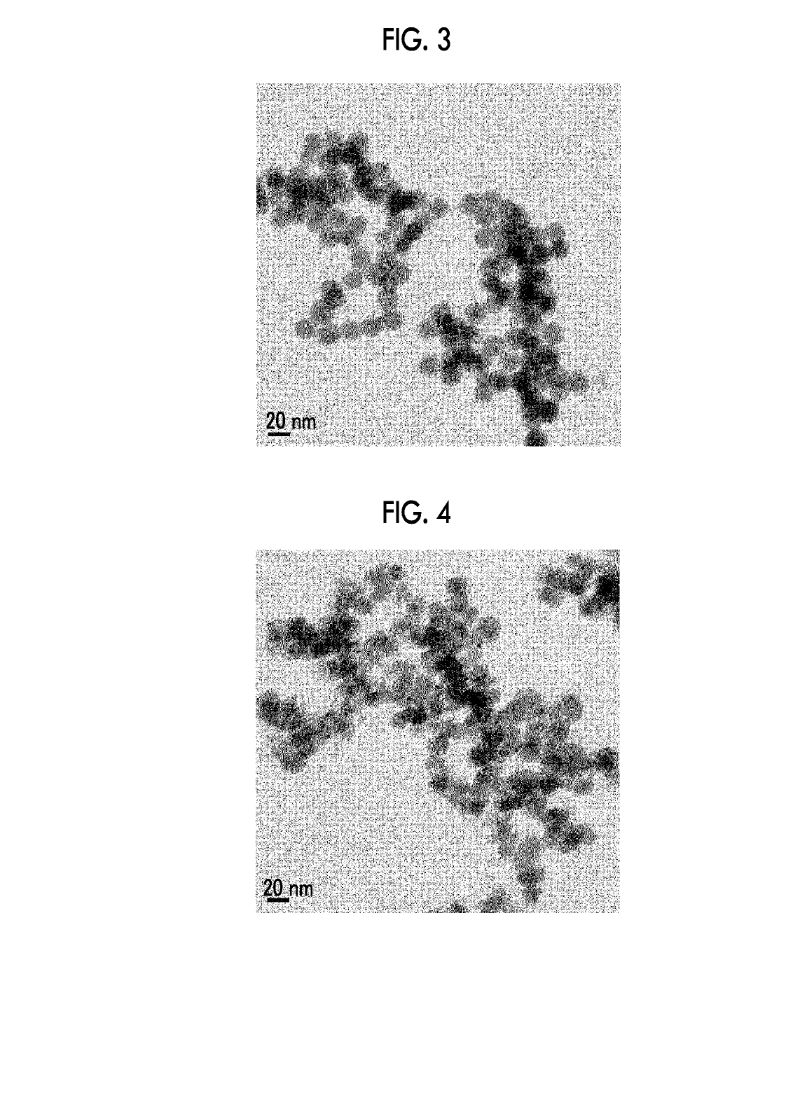

FIGS. 2 to 5 show TEM images of the semiconductor nanoparticle complexes prepared in Example 1, Example 2, Comparative Example 1 and Comparative Example 2, respectively.

Here, JEM 1400 Plus (manufactured by JEOL Co., Ltd.) was used as a transmission electron microscope, and observation was carried out at a magnification of 400,000 times under the measurement conditions of an acceleration voltage of 80 kV. It is presumed that the spherical structure of about 20 nm is silica as an oxide, and it is considered that a granular image which exhibits the strong contrast in silica and is present at about 3 nm is indicative of the semiconductor nanoparticle QDs.

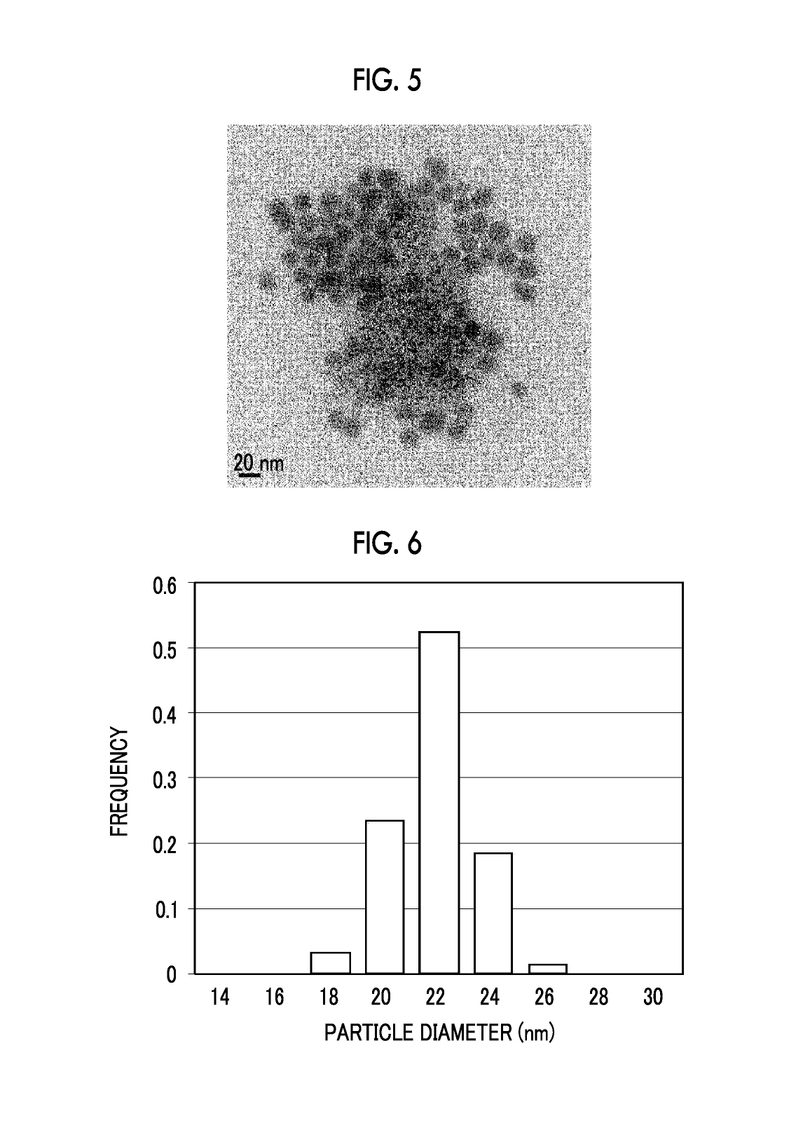

FIG. 6 is a graph showing the particle size distribution of the semiconductor nanoparticle complex prepared in Example 1.

Here, with regard to the particle size distribution, upon circumscribing a circle having the smallest area for one semiconductor nanoparticle complex in the TEM image observed under the above measurement conditions and defining the diameter of the circle as the particle diameter, the distribution of the particle size was prepared for approximately 50 semiconductor nanoparticle complexes.

[Evaluation]

For the prepared semiconductor nanoparticle complexes, the magnitude of the difference between the emission peak before coating with a silane, that is, of the semiconductor nanoparticle QDs and the emission peak of the semiconductor nanoparticle complex after formation of the oxide-containing layer was calculated as “peak shift”. The results are shown in Table 1 below. It is shown that samples with smaller peak shift are better quality particles with fewer defects in oxide coatings.

In addition, the presence or absence of aggregation of the semiconductor nanoparticle QDs was confirmed from a TEM image (magnification: 100,000 times) of the dispersion liquid of the prepared semiconductor nanoparticle complex. The results are shown in Table 1 below.

TABLE 1

| | | Oxide-containing | Emission | |
|---|---|---|---|---|
| | | layer forming step | wavelength | |
| | Coating step (silane) | (alkoxide) | peak shift | Aggregation |
| Example 1 | Mercaptoundecyltrimethoxysilane | TEOS | 2 nm | None |
| Example 2 | Mercaptoundecyltrimethoxysilane | TEOS | 10 nm | Almost none |
| Comparative | Mercaptoundecyltrimethoxysilane | TEOS | 18 nm | Present |
| Example 1 | | | | |
| Comparative | TEOS | TEOS | 39 nm | Present |
| Example 2 | | | | |

From the results shown in Table 1, in the case of being coated with TEOS before the hydrophilization treatment, wavelength shift became large and as shown in FIG. 5, more aggregates were confirmed (Comparative Example 2).

In addition, in the case of being coated with a silane having an alkylene group having less than 8 carbon atoms, there was a tendency of improvement compared with Comparative Example 2, but the wavelength shift became large, and as shown in FIG. 4, aggregates were confirmed (Comparative Example 1).

On the other hand, in the case of being coated with a silane having an alkylene group having 8 to 17 carbon atoms, aggregation of the semiconductor nanoparticle QDs was not observed, and it was found that the peak shift of the emission wavelength became smaller even after the oxide-containing layer was formed and therefore a good coating with an oxide was formed (Examples 1 and 2).

Further, from the results shown in FIG. 6, it was found that the semiconductor nanoparticle complex prepared in Example 1 exhibited no detection of a specific size component showing an aggregate, and the formation of a semiconductor nanoparticle complex having a uniform particle diameter.

### EXPLANATION OF REFERENCES

10: semiconductor nanoparticle complex
11: semiconductor nanoparticles
12: coating layer
13: oxide-containing layer

What is claimed is:

1. A method for producing a semiconductor nanoparticle complex, comprising:
a coating step of coating a semiconductor nanoparticle with a silane having a group represented by Formula (1) to obtain a coated semiconductor nanoparticle;
a hydrophilization step of mixing the coated semiconductor nanoparticle with a reverse micelle solution to obtain a reverse micelle solution containing a hydrophilized coated semiconductor nanoparticle; and
an oxide-containing layer forming step of forming an oxide-containing layer on the surface of the hydrophilized coated semiconductor nanoparticle by adding an alkoxide to the reverse micelle solution after the hydrophilization step to obtain the semiconductor nanoparticle complex,
X-L-* (1)
in Formula (1), X represents an active hydrogen-containing group, L represents an alkylene group having 8 to 17 carbon atoms, and * represents a bonding position with a silicon atom.

2. The method for producing a semiconductor nanoparticle complex according to claim 1, wherein the semiconductor nanoparticle contains a Group III element and a Group V element.

3. The method for producing a semiconductor nanoparticle complex according to claim 2, wherein the Group III element is In and the Group V element is any one of P, N, or As.

4. The method for producing a semiconductor nanoparticle complex according to claim 3, wherein the Group III element is In and the Group V element is P.

5. The method for producing a semiconductor nanoparticle complex according to claim 1, wherein the silane is represented by Formula (2),
X-L-Si(OR)₃ (2)
in Formula (2), X represents an active hydrogen-containing group, L represents an alkylene group having 8 to 17 carbon atoms, R represents a methyl group or an ethyl group, and a plurality of R's may be the same or different.

6. The method for producing a semiconductor nanoparticle complex according to claim 1, wherein the active hydrogen-containing group is any one of a mercapto group, a carboxyl group, a hydroxyl group, an amino group, a phosphate group, or a sulfo group.

7. The method for producing a semiconductor nanoparticle complex according to claim 6, wherein the active hydrogen-containing group is a mercapto group.

8. The method for producing a semiconductor nanoparticle complex according to claim 1, wherein the alkoxide is an alkoxysilane.

9. The method for producing a semiconductor nanoparticle complex according to claim 8, wherein an oxide contained in the oxide-containing layer is silica.

10. A semiconductor nanoparticle complex comprising:
a semiconductor nanoparticle;
a coating layer covering at least a part of the semiconductor nanoparticle; and
an oxide-containing layer covering at least a part of the coating layer, wherein the coating layer has a structure represented by Formula (3),
*₁-Y-L-*₂ (3)
in Formula (3), Y represents a divalent group obtained by removing active hydrogen from an active hydrogen-containing group, L represents an alkylene group having 8 to 17 carbon atoms, *₁ represents a bonding position with the semiconductor nanoparticle, and *₂ represents a bonding position with the oxide-containing layer.

11. The semiconductor nanoparticle complex according to claim 10, wherein the semiconductor nanoparticle contains a Group III element and a Group V element.

12. The semiconductor nanoparticle complex according to claim 11, wherein the Group III element is In and the Group V element is any one of P, N, or As.

13. The semiconductor nanoparticle complex according to claim 12, wherein the Group III element is In and the Group V element is P.

14. The semiconductor nanoparticle complex according to claim 10, wherein the active hydrogen-containing group is any one of a mercapto group, a carboxyl group, a hydroxyl group, an amino group, a phosphate group, or a sulfo group.

15. The semiconductor nanoparticle complex according to claim 11, wherein the active hydrogen-containing group is any one of a mercapto group, a carboxyl group, a hydroxyl group, an amino group, a phosphate group, or a sulfo group.

16. The semiconductor nanoparticle complex according to claim 12, wherein the active hydrogen-containing group is any one of a mercapto group, a carboxyl group, a hydroxyl group, an amino group, a phosphate group, or a sulfo group.

17. The semiconductor nanoparticle complex according to claim 13, wherein the active hydrogen-containing group is any one of a mercapto group, a carboxyl group, a hydroxyl group, an amino group, a phosphate group, or a sulfo group.

18. The semiconductor nanoparticle complex according to claim 14, wherein the active hydrogen-containing group is a mercapto group.

19. The semiconductor nanoparticle complex according to claim 15, wherein the active hydrogen-containing group is a mercapto group.

20. A film comprising the semiconductor nanoparticle complex according to claim 10.
